(19) United States
(12) Patent Application Publication
(10) Pub. No.: US 2025/0227972 A1
(43) Pub. Date: Jul. 10, 2025

(54) HIGH ELECTRON MOBILITY TRANSISTOR AND SEMICONDUCTOR DEVICE

(71) Applicant: Sony Semiconductor Solutions Corporation, Kanagawa (JP)

(72) Inventor: Tatsuma Saito, Kanagawa (JP)

(21) Appl. No.: 18/853,873

(22) PCT Filed: Apr. 11, 2023
(86) PCT No.: PCT/JP2023/014741

§ 371 Date: Oct. 3, 2024

(30) Foreign Application Priority Data
May 24, 2022 (JP) 2022-084836

(51) Int. Cl. H10D 62/824; H10D 30/47; H10D 64/27

(52) U.S. Cl. CPC H10D 62/824; H10D 30/475; H10D 64/411; H10D 64/512

(57) ABSTRACT

A high electron mobility transistor includes: a channel layer through which carriers are to flow; a pair of respective main electrodes coupled to one end and another end of the channel layer; a barrier layer that is disposed at the channel layer and induces the carriers; a gate electrode disposed at an intermediate part of the channel layer with the barrier layer interposed therebetween; a first spacer layer that is disposed between the channel layer and the barrier layer and decreases alloy scattering; and a second spacer layer that is disposed between the first spacer layer and the barrier layer in a region overlapping the gate electrode and traps the carriers.

### TECHNICAL FIELD

The present disclosure relates to a high electron mobility transistor and a semiconductor device. The present disclosure further relates to a high frequency switch circuit, a power amplifier, and a wireless communication terminal each including the high electron mobility transistor.

### BACKGROUND ART

PTL 1 discloses a high electron mobility transistor (HEMT: high electron mobility transistor, hereinafter, simply referred to as a “HEMT”). The HEMT includes a nitride semiconductor, particularly GaN, as a group III-V compound semiconductor. The GaN HEMT has features such as high voltage resistance, high heat resistance, high saturated electron velocity, or high channel electron concentration. Such features enable achievement of a smaller GaN HEMT having higher performance, promoting the development for its application to a power device and a high frequency device.

The GaN HEMT includes: a channel layer; a spacer layer stacked on the channel layer; and a barrier layer stacked on the spacer layer. The channel layer is a current-carrying path through which carriers (electrons) are to flow. The spacer layer suppresses alloy scattering. The barrier layer induces the carriers to an interface between the channel layer and the spacer layer.

In the GaN HEMT for which an insulated gate structure (hereinafter, simply referred to as an “MIS (metal insulated semiconductor) type”) is adopted, a gate electrode is disposed on the barrier layer with an insulating layer (a gate insulating film) interposed therebetween. The adoption of the MIS type enables achievement of low loss and high output of the GaN HEMT.

### CITATION LIST

### Patent Literature

PTL 1: Japanese Unexamined Patent Application Publication No. 2018-56299

### SUMMARY OF THE INVENTION

In the process of research and development of a GaN HEMT, the inventors of the present application have confirmed the following phenomenon. Carrier trap regions (carrier trap regions) are present at an interface between an insulating layer and a barrier layer, in a bulk of the insulating layer, and in a bulk of the barrier layer. When a high electric field or a high temperature stress is repeatedly applied to the GaN HEMT in driving, carriers are trapped in the carrier trap region. Trapping the carriers causes fluctuation in a threshold voltage of the GaN HEMT.

Accordingly, it is desirable to effectively suppress or prevent fluctuation in a threshold voltage of a HEMT in the HEMT and a semiconductor device including the HEMT.

A HEMT according to a first embodiment of the present disclosure includes: a channel layer through which carriers are to flow; a pair of respective main electrodes coupled to one end and another end of the channel layer; a barrier layer that is disposed at the channel layer and induces the carriers; a gate electrode disposed at an intermediate part of the channel layer with the barrier layer interposed therebetween; a first spacer layer that is disposed between the channel layer and the barrier layer and decreases alloy scattering; and a second spacer layer that is disposed between the first spacer layer and the barrier layer in a region overlapping the gate electrode and traps the carriers.

A semiconductor device according to a second embodiment of the disclosure includes a HEMT, in which the HEMT includes a channel layer through which carriers are to flow, a pair of respective main electrodes coupled to one end and another end of the channel layer, a barrier layer that is disposed at the channel layer and induces the carriers, a gate electrode disposed at an intermediate part of the channel layer with the barrier layer interposed therebetween, a first spacer layer that is disposed between the channel layer and the barrier layer and decreases alloy scattering, and a second spacer layer that is disposed between the first spacer layer and the barrier layer in a region overlapping the gate electrode and traps the carriers.

### BRIEF DESCRIPTION OF THE DRAWINGS

FIG. 1 is a cross-sectional view of a main part of a semiconductor device including a HEMT according to a first embodiment of the present disclosure.

FIG. 2 is a composition profile diagram of the HEMT illustrated in FIG. 1.

FIG. 3 is an energy band structure diagram of the HEMT illustrated in FIG. 1.

FIG. 4 is a current-voltage characteristic diagram of the HEMT illustrated in FIG. 1.

FIG. 5 is a current-voltage characteristic diagram of a HEMT according to a comparative example.

FIG. 6 is a configuration diagram illustrating compositions of respective semiconductor layers of the HEMT according to the first embodiment and compositions of respective semiconductor layers of the HEMT according to the comparative example.

FIG. 7 is a cross-sectional view, corresponding to FIG. 1, of a main part of a semiconductor device including a HEMT according to a second embodiment of the present disclosure.

FIG. 8 is a configuration diagram, corresponding to FIG. 6, illustrating compositions of respective semiconductor layers of a HEMT according to a third embodiment of the present disclosure.

FIG. 9 is a configuration diagram, corresponding to FIG. 6, illustrating compositions of respective semiconductor layers of a HEMT according to a fourth embodiment of the present disclosure.

FIG. 10 is a perspective view of a semiconductor module including a HEMT according to a fifth embodiment of the present disclosure.

FIG. 11 is a block configuration diagram of an electronic apparatus including a HEMT according to a sixth embodiment of the present disclosure.

### MODES FOR CARRYING OUT THE INVENTION

Hereinafter, detailed description is given of embodiments of the present disclosure with reference to the drawings. It is to be noted that the description is given in the following order.

### 1. First Embodiment

A first embodiment is a first example in which the present technology is applied to a HEMT and a semiconductor device including the HEMT. Here, description is given of a vertical cross-sectional structure, a composition profile, an energy band structure, and current-voltage characteristics of a HEMT including a nitride semiconductor as a group II-V compound semiconductor, particularly an MIS GaN HEMT.

### 2. Second Embodiment

A second embodiment is a second example in which the present technology is applied to a Schottky junction (Schottky barrier junction) GaN HEMT and a semiconductor device including this HEMT in place of the MIS GaN HEMT in the semiconductor device according to the first embodiment.

### 3. Third Embodiment

A third embodiment is a third example in which the present technology is applied to an MIS GaN HEMT having a different structure and a semiconductor device including this HEMT in the semiconductor device according to the first embodiment.

### 4. Fourth Embodiment

A fourth embodiment is a fourth example in which the present technology is applied to a GaO HEMT and a semiconductor device including this HEMT in place of the MIS GaN HEMT in the semiconductor device according to the first embodiment.

### 5. Fifth Embodiment

A fifth embodiment describes a semiconductor module in which any one of the semiconductor devices according to the first embodiment to the fourth embodiment is mounted. The semiconductor module is incorporated into, for example, a wireless communication terminal. Further, the semiconductor module includes a high frequency switch circuit, a power amplifier, and the like.

### 6. Sixth Embodiment

A sixth embodiment describes an electronic apparatus in which any one of the semiconductor devices according to the first embodiment to the fourth embodiment is mounted. The electronic apparatus is, for example, a wireless communication terminal. Further, the electronic apparatus includes a high frequency switch circuit, a power amplifier, and the like.

### 7. Other Embodiments

### 1. First Embodiment

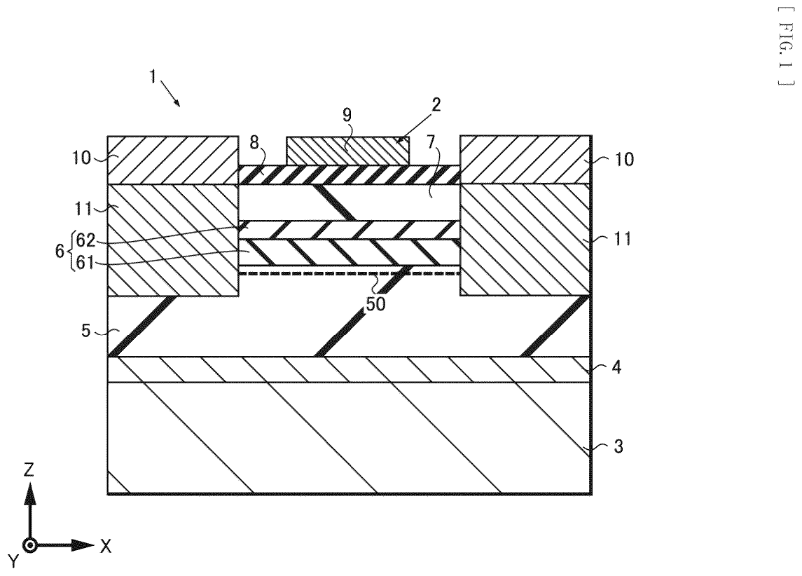

Description is given of a HEMT 2 according to a first embodiment of the present disclosure and a semiconductor device 1 including the HEMT 2 according to the first embodiment of the present disclosure with reference to FIGS. 1 to 6.

Here, an arrow-X direction illustrated as appropriate in the drawings indicates one planar direction of the semiconductor device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each illustrated to aid understanding of description, and are not intended to limit directions of the present technology.

### Configuration of HEMT 2 and Semiconductor Device 1

### (1) Basic Structure of HEMT 2 and Semiconductor Device 1

FIG. 1 illustrates an example of a vertical cross-sectional structure of a main part of the semiconductor device 1 according to the first embodiment.

As illustrated in FIG. 1, for the HEMT 2 and the semiconductor device 1 according to the first embodiment, a substrate 3 serves as a base. In the first embodiment, the HEMT 2 is formed by an MIS GaN HEMT. That is, the HEMT 2 includes a channel layer 5, a spacer layer 6, a barrier layer 7, an insulating layer 8, a gate electrode 9, and a pair of main electrodes 10.

### (2) Configuration of Substrate 3

The substrate 3 includes a compound semiconductor material, e.g., a nitride semiconductor material as a group III-V compound semiconductor material. Specifically, a semi-insulating single-crystal GaN is used.

In the first embodiment, a buffer layer 4 is disposed between the substrate 3 and the channel layer 5. The buffer layer 4 controls a lattice constant. Accordingly, it is possible for the substrate 3 to include a semiconductor material having a lattice constant different from that of the channel layer 5. For example, a substrate such as a SiC substrate, a sapphire substrate, or a Si substrate is usable for the substrate 3.

### (3) Configuration of Buffer Layer 4

The buffer layer 4 is stacked on the substrate 3. The buffer layer 4 includes, for example, a compound semiconductor material. The compound semiconductor material is formed on the substrate 3 using an epitaxial growth method.

In a case where the lattice constant of the channel layer 5 is different from the lattice constant of the substrate 3, the lattice constants are controlled by the buffer layer 4. Controlling the lattice constants allows the channel layer 5 to have a favorable crystalline quality. Further, in a manufacturing method of the semiconductor device 1, it is possible to control warpage of the substrate 3 being in a wafer state after formation of the channel layer 5.

For example, in a case where the substrate 3 includes single-crystal Si and the channel layer 5 includes GaN, it is possible for the buffer layer 4 to include AIN, AlGaN, or GaN.

### (4) Configuration of Channel Layer 5

The channel layer 5 is stacked on the buffer layer 4. A two-dimensional electron gas (2DEG) 50 is generated adjacent to the spacer layer 6 of the channel layer 5. The two-dimensional electron gas 50 is a region in which carriers accumulate by a difference in a polarization charge amount with the barrier layer 7.

One end in the arrow-X direction of the two-dimensional electron gas 50 is electrically coupled to one of the pair of main electrodes 10. Another end in an opposite direction in the arrow-X direction of the two-dimensional electron gas 50 is electrically coupled to another one of the pair of main electrodes 10. That is, the one end and the other end of the channel layer 5 are coupled to the pair of respective main electrodes 10, allowing the channel layer 5 to configure a portion of a current path through which the carriers are to flow.

Here, the channel layer 5 includes a nitride semiconductor material. Specifically, the channel layer 5 includes, for example, GaN. The GaN is formed using the epitaxial growth method.

It is also possible for the channel layer 5 to include undoped GaN (u-GaN) that is not doped with an impurity. Use of the u-GaN makes it possible to effectively suppress impurity scattering of the carriers in the channel layer 5, thus achieving high carrier mobility.

### (5) Configuration of Spacer Layer 6

The spacer layer 6 includes a first spacer layer 61 and a second spacer layer 62.

The first spacer layer 61 is stacked on the channel layer 5 and disposed between the channel layer 5 and the barrier layer 7. The second spacer layer 62 is stacked on the first spacer layer 61 and disposed between the first spacer layer 61 and the barrier layer 7.

Further, the second spacer layer 62 is disposed at least in a region overlapping the gate electrode 9, as viewed in the arrow-Y direction (hereinafter, simply referred to as “in a side view”) and as viewed in the arrow-Z direction (hereinafter, simply referred to as “in a plan view”).

Here, the region overlapping the gate electrode 9 includes a region overlapping a portion of the gate electrode 9, a region overlapping the entire gate electrode 9, and a region overlapping an area wider than the entire gate electrode 9, in the side view and in the plan view. For example, the second spacer layer 62 may be disposed in a region overlapping a portion of the gate electrode 9 being on a side of the main electrode 10 used as a drain electrode.

### (5-1) Configuration of First Spacer Layer 61

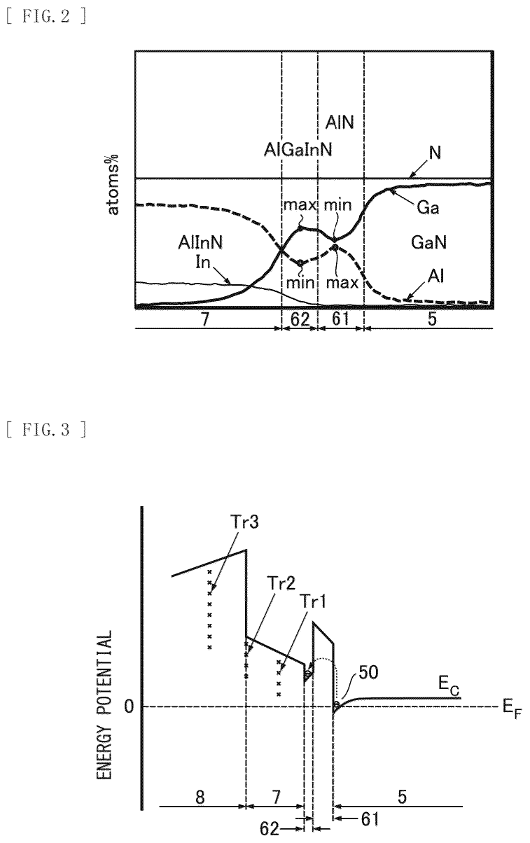

FIG. 2 illustrates an example of a composition profile of the HEMT 2. In FIG. 2, the horizontal axis indicates, from the right side to the left side, respective regions of the channel layer 5, the first spacer layer 61, the second spacer layer 62, and the barrier layer 7. The vertical axis indicates constituent element contents [atoms %].

Further, FIG. 3 illustrates an example of an energy band structure of the HEMT 2. In FIG. 3, the horizontal axis indicates, from the right side to the left side, respective regions of the channel layer 5. the first spacer layer 61, the second spacer layer 62, the barrier layer 7, and the insulating layer 8. The vertical axis indicates energy potential.

Referring back to FIG. 1, the first spacer layer 61 includes a nitride semiconductor material having a band gap larger than a band gap (3.4 [eV]) of the channel layer 5. The first spacer layer 61 is formed using, for example, the epitaxial growth method.

As illustrated in FIG. 2, the first spacer layer 61 includes Alₓ₁In_{y1}Ga_{[1-x1-y1}]N (0<x1<1, 0≤y<1, and 0<x1+y1<1). As illustrated in FIG. 3, a band gap of the first spacer layer 61 including the nitride semiconductor material is wider than the band gap of the channel layer 5.

To give detailed description, it is possible for the first spacer layer 61 to include, for example, AlN as a binary nitride semiconductor material. It is also possible for the first spacer layer 61 to include, for example, AlGaN as a ternary nitride semiconductor material. In addition, it is possible for the first spacer layer 61 to include, for example, AlGaInN as a quaternary nitride semiconductor material.

In the first embodiment, description is given of the first spacer layer 61 in a case where AlN is used.

When the first spacer layer 61 is disposed between the channel layer 5 and the barrier layer 7, induced carriers accumulate at an interface of the channel layer 5 adjacent to the first spacer layer 61 to generate the two-dimensional electron gas 50. Although described later, the barrier layer 7 includes, for example, a ternary nitride semiconductor material. The first spacer layer 61 makes it possible to decrease an influence of alloy scattering from the barrier layer 7, thereby increasing carrier mobility.

Here, in a manufacturing method of the HEMT 2, the first spacer layer 61 is formed on the channel layer 5 by crystal growth using the epitaxial growth method. Accordingly, Ga as a constituent element of the channel layer 5 is diffused in the first spacer layer 61. This allows the first spacer layer 61 to contain Ga.

As illustrated in FIG. 2, in a Ga composition profile, a Ga composition ratio decreases in a crystal growth direction, that is, from the channel layer 5 to the first spacer layer 61. Due to a thermal history obtained until completion of crystal growth of the barrier layer 7, the Ga composition ratio increases again from the first spacer layer 61 to the second spacer layer 62. Accordingly, the first spacer layer 61 has a Ga composition profile having a minimal value (min) at an intermediate part in a thickness direction.

It is to be noted that a similar Ga composition profile may be formed by controlling a supply amount of a semiconductor crystal growth material and intentionally adding Ga.

Meanwhile, Al that is the same III group material and enters the same crystal lattice position is influenced by the Ga diffusion. Consequently, in an Al composition profile, an Al composition ratio increases from the channel layer 5 to the first spacer layer 61, in contrast to the Ga composition profile. Further, the Al composition ratio decreases again due to the thermal history from the first spacer layer 61 to the second spacer layer 62. Accordingly, the first spacer layer 61 has an Al composition profile having a maximal value (max) at an intermediate part in the thickness direction.

It is to be noted that a N composition ratio is constant.

### (5-2) Configuration of Second Spacer Layer 62

As illustrated in FIG. 1, the second spacer layer 62 includes a nitride semiconductor material having a band gap smaller than the band gap of the first spacer layer 61. The second spacer layer 62 is formed using, for example, the epitaxial growth method.

As illustrated in FIG. 2, in a case where the channel layer 5 includes GaN, it is possible for the second spacer layer 62 to include a nitride semiconductor material including Al, Ga, and In. Specifically, the second spacer layer 62 includes Alₓ₂In_{y2}Ga_{[1-x2-y2]}N (0<x2<1, 0<y2<1, and 0<x2+y2<1). It is to be noted that AlInGaN is denoted as AlGaInN in FIG. 2 and the like, but AlInGaN and AlGaInN are the same material.

Here, constituent element ratios x1 and y1 of the first spacer layer 61 and constituent element ratios x2 and y2 of the second spacer layer 62 each satisfy a relational expression <1> and a relational expression <2> below.

x1>x2 <1>

x1+y1>x2+y2 <2>

As illustrated in FIG. 3, a band gap of the second spacer layer 62 including the nitride semiconductor material is narrower than the band gap of the first spacer layer 61 and a band gap of the barrier layer 7 described later. Further, the band gap of the second spacer layer 62 is wider than the band gap of the channel layer 5.

Therefore, the second spacer layer 62 has concave energy potential formed to be curved toward a side of a Fermi level E_{F} with respect to energy potential of the first spacer layer 61 and energy potential of the barrier layer 7. The energy potential of the first spacer layer 61 and the energy potential of the barrier layer 7 are indicated by a conduction band E_{C} (see FIG. 3). Even in a state where a positive bias is applied to the gate electrode 9 in driving, the energy potential (the conduction band E_{C}) of the second spacer layer 62 is higher than the conduction band E_{C} of the channel layer 5 and the Fermi level E_{F}.

Further, the second spacer layer 62 including a quaternary nitride semiconductor material as described above allows for easy formation of a mixed crystal having superior single crystallinity to that of a nitride semiconductor material used in the barrier layer 7 described later.

As illustrated in FIG. 3, carriers (here, for example, electrons) generated by stresses in driving and transitioning from the two-dimensional electron gas 50 to a side of the gate electrode 9 are trapped (trapped) in an energy potential region of the second spacer layer 62 in the HEMT 2. The stresses include at least a voltage application stress and a high temperature application stress. That is, the second spacer layer 62 forms a region that traps the carriers.

Further, as illustrated in FIG. 3, the HEMT 2 includes a bulk trap region Tr1 generated in the barrier layer 7, an interface trap region Tr2 generated at an interface between the barrier layer 7 and the insulating layer 8, and a bulk trap region Tr3 generated in the insulating layer 8. The HEMT 2 including the second spacer layer 62 makes it possible to decrease a crystal defect level at an interface between the first spacer layer 61 and the barrier layer 7.

Furthermore, as a thickness of the spacer layer 6 including the first spacer layer 61 and the second spacer layer 62 increases, surface morphology of the barrier layer 7 tends to deteriorate. Meanwhile, an excessively small thickness of the spacer layer 6 makes it unable to achieve effects provided by including the spacer layer 6, significantly exhibiting the alloy scattering. This decreases the carrier mobility.

Therefore, the thickness of the spacer layer 6 including the first spacer layer 61 and the second spacer layer 62 is formed to be equal to or less than 3 mm. A thickness of the first spacer layer 61 is formed to be, for example, equal to or more than 0.5 nm. Further, a thickness of the second spacer layer 62 is formed to be smaller than the thickness of the first spacer layer 61.

### (6) Configuration of Barrier Layer 7

As illustrated in FIG. 1, the barrier layer 7 includes a nitride semiconductor material having a band gap larger than the band gap of the channel layer 5. The barrier layer 7 is formed using, for example, the epitaxial growth method.

As illustrated in FIG. 2, the barrier layer 7 includes Alₓ₃In_{[1-x3]}N (0<x3<1). The constituent element ratio x2 of the second spacer layer 62 and a constituent element ratio x3 of the barrier layer 7 each satisfy a relational expression <3> below.

x3>x2 <3>

As illustrated in FIG. 3, the band gap of the barrier layer 7 including the nitride semiconductor material is narrower than the band gap of the first spacer layer 61 and is wider than the band gap of the second spacer layer 62.

Further, it is possible for the barrier layer 7 to include undoped AlInN (u-AlInN) that is not doped with an impurity. The barrier layer 7 including the u-AlInN makes it possible to effectively suppress the impurity scattering of the carriers in the channel layer 5. This makes it possible to achieve high carrier mobility.

Furthermore, it is sufficient for the barrier layer 7 to be a compound semiconductor material that allows the carriers to accumulate at the interface of the channel layer 5 adjacent to the first spacer layer 61 by the difference in the polarization charge amount with the channel layer 5 to generate the two-dimensional electron gas 50. In a case where the channel layer 5 is a compound semiconductor material containing Al or In without limitation to GaN as described above, it is possible for the barrier layer 7 to include, for example, Al_{1-x-y}InₓGa_{y}N (0≤x<1, 0≤y<1, and x+y≤1). It is possible to form the AlInGaN using, for example, the epitaxial growth method.

It is also possible for the barrier layer 7 to include undoped AlInGaN.

### (7) Configuration of Main Electrode 10

As illustrated in FIG. 1, the pair of respective main electrodes 10 is electrically coupled to the one end and the other end of the channel layer 5. The one of the pair of main electrodes 10 is used as a source electrode, and the other one of the pair of main electrodes 10 is used as a drain electrode. In the first embodiment, the main electrodes 10 are each coupled to the channel layer 5 with a contact layer 11 interposed therebetween.

The main electrodes 10 are each formed by, for example, a composite film in which Ti, Al, Ni, and Au are sequentially stacked.

It is to be noted that a structure in which the main electrodes 10 are each directly coupled to the channel layer 5 may be adopted for the HEMT 2.

### (8) Configuration of Contact Layer 11

As illustrated in FIG. 1, the contact layer 11 is interposed between the channel layer 5 and the corresponding main electrode 10 and is disposed at the corresponding end of the channel layer 5. The contact layer 11 forms a portion of the current path between the pair of main electrodes 10. Here, the contact layer 11 includes GaN that is the same nitride semiconductor material as that of the channel layer 5.

Further, the contact layer 11 may include InₓGa₁₋₋ₓN (0≤x≤1) that is able to grow at a lower temperature than GaN.

In the manufacturing method of the HEMT 2, the contact layer 11 is formed on the channel layer 5 only in a formation region of the main electrode 10 using a selection mask in which the formation region of the main electrode 10 is opened. At this time. the contact layer 11 is formed using the epitaxial growth method.

Further, in a case where growth conditions achieving low selective growth characteristics are used, the contact layer 11 is first grown in the formation region of the main electrode 10 and on the selection mask. Thereafter, the selection mask and the contact layer 11 grown on the selection mask are removed. Consequently, the contact layer 11 is formed only in the formation region of the main electrode 10.

The contact layer 11 is doped with an impurity at high density to reduce contact resistance with the main electrodes 10 to thereby form ohmic connection (ohmic contact). The HEMT 2 according to the first embodiment is of an n-channel electrically conductive type. Accordingly, an n-type impurity is used as the impurity. For example, it is possible to use, for example, Si or Ge as the n-type impurity. Further, impurity density of the contact layer 11 is set to, for example, 1×10¹⁹ [atoms/cm⁻³] or more.

### (9) Configuration of Insulating Layer 8

As illustrated in FIG. 1, the insulating layer 8 is disposed at an intermediate part of the channel layer 5 between the pair of main electrodes 10. Further, the insulating layer 8 is disposed on the barrier layer 7 between the barrier layer 7 and the gate electrode 9. It is sufficient for the insulating layer 8 to be disposed at least immediately below the gate electrode 9.

The insulating layer 8 is a gate insulating film. The insulating layer 8 is insulated from each of the barrier layer 7 and the gate electrode 9. For the insulating layer 8, it is possible to use at least one or more dielectric films of a material selected from, for example, SiO₂, Si₃N₄, and HfO₂ serving as a high dielectric constant material.

### (10) Configuration of Gate Electrode 9

As illustrated in FIG. 1, the gate electrode 9 is disposed on the insulating layer 8. For example, a composite film in which Ni and Au are sequentially stacked is used for the gate electrode 9.

### [Current-Voltage Characteristics of HEMT 2]

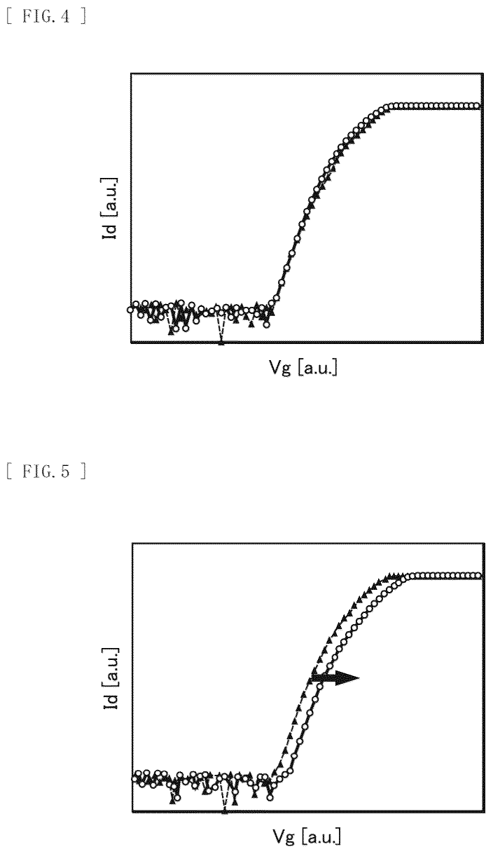

FIG. 4 illustrates an example of current-voltage characteristics of the HEMT 2 according to the first embodiment. The horizontal axis indicates a gate voltage Vg [a.u.]. The vertical axis indicates a drain current Id [a.u.]. The symbol “▴” indicates current-voltage characteristics at an early stage of driving the HEMT 2. The symbol “∘” indicates current-voltage characteristics after application of stresses to the HEMT 2.

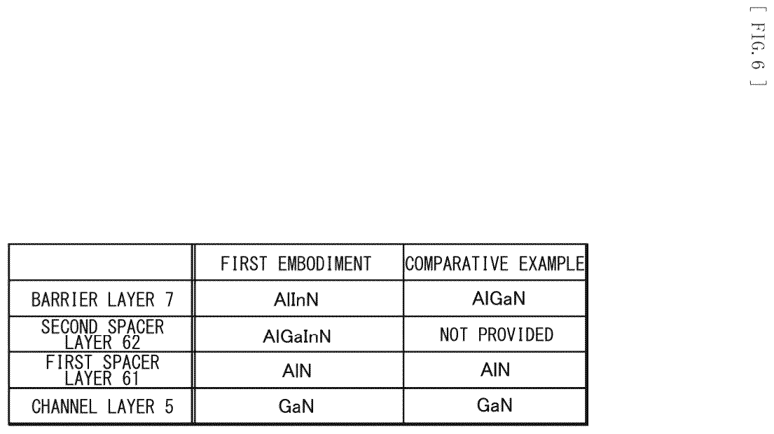

Further, FIG. 5 illustrates an example of current-voltage characteristics of a HEMT according to a comparative example. The horizontal axis, the vertical axis, and the symbols respectively indicate the same as the horizontal axis, the vertical axis, and the symbols illustrated in FIG. 4.

Furthermore, FIG. 6 illustrates an example of configurations of constituent elements of respective semiconductor layers of the HEMT 2 according to the first embodiment and constituent elements of respective semiconductor layers of the HEMT according to the comparative example.

First, the HEMT according to the comparative example is not provided with the second spacer layer 62, as illustrated in FIG. 6. In the HEMT 2 according to the first embodiment, the second spacer layer 62 is disposed between the first spacer layer 61 and the barrier layer 7. That is, the HEMT according to the comparative example has a configuration in which the barrier layer 7 is disposed directly on the first spacer layer 61.

As illustrated in FIG. 5, the HEMT according to the comparative example has a phenomenon in which the current-voltage characteristics after the stress application shift toward a high voltage side with respect to the current-voltage characteristics at the early stage of driving.

To give detailed description, as the stresses increase, a shift amount of the current-voltage characteristics increases. This increases a threshold voltage of the HEMT. One reason for this is presumed to be that, due to driving the HEMT, carriers (electrons) transitioning in a direction of the gate electrode from the two-dimensional electron gas are trapped in one of the bulk trap region Tr1, the interface trap region Tr2, or the bulk trap region Tr3 illustrated in FIG. 3 described above.

Unlike the HEMT according to the comparative example, the HEMT 2 according to the first embodiment includes the second spacer layer 62, as illustrated in FIGS. 1 to 3 and 6.

As illustrated in FIG. 4, the current-voltage characteristics after the stress application substantially do not change with respect to the current-voltage characteristics at the early stage of driving. That is, even with an increase in the stresses, the threshold voltage of the HEMT 2 is constant. This results in no change in the threshold voltage.

Detailed description is given of this point. The carriers (electrons) generated by driving the HEMT 2 and transitioning in the direction of the gate electrode 9 from the two-dimensional electron gas 50 are trapped by energy potential generated by the second spacer layer 62 before being trapped in the bulk trap region Tr1, the interface trap region Tr2, or the bulk trap region Tr3 (see FIG. 3).

Because the thickness of the first spacer layer 61 is small, the trapped carriers transition to a side of the two-dimensional electron gas 50 through the first spacer layer 61 by a tunneling phenomenon.

Further, in the first embodiment, one end and another end of the second spacer layer 62 are disposed in contact with the contact layer 11. Therefore, driving the HEMT 2 allows the trapped carriers to flow between the pair of main electrodes 10 to be removed.

### [Workings and Effects]

As illustrated in FIGS. 1 to 3 and 6, the HEMT 2 according to the first embodiment includes the channel layer 5, the pair of main electrodes 10, the barrier layer 7, the gate electrode 9, and the first spacer layer 61.

The carriers flow through the channel layer 5. The pair of respective main electrodes 10 is coupled to the one end and the other end of the channel layer 5. The barrier layer 7 is disposed at the channel layer 5 and induces the carriers. The gate electrode 9 is disposed at the intermediate part of the channel layer 5 with the barrier layer 7 interposed therebetween. The first spacer layer 61 is disposed between the channel layer 5 and the barrier layer 7 and decreases the alloy scattering.

Here, the HEMT 2 further includes the second spacer layer 62. The second spacer layer 62 is disposed between the first spacer layer 61 and the barrier layer 7 in the region overlapping the gate electrode 9 and traps the carriers. The carriers are trapped in the second spacer layer 62 before being trapped in each of the bulk trap region Tr1 present in the barrier layer 7, the interface trap region Tr2 present at the interface between the barrier layer 7 and the insulating layer 8, and the bulk trap region Tr3 present in the insulating layer 8 illustrated in FIG. 3.

Such a configuration makes it possible to effectively suppress or prevent the carriers being trapped in each of the bulk trap region Tr1, the interface trap region Tr2, and the bulk trap region Tr3, even when a high electric field or a high temperature stress is repeatedly applied in driving. Consequently, as illustrated in FIG. 4. this configuration makes it possible to effectively suppress or prevent fluctuation in the threshold voltage of the HEMT 2.

Further, as illustrated in FIG. 3, the band gap of the second spacer layer 62 is narrower than the respective band gaps of the first spacer layer 61 and the barrier layer 7 and is wider than the band gap of the channel layer 5 in the HEMT 2. Such a configuration allows the second spacer layer 62 of the HEMT 2 to have the concave energy potential formed to be curved toward the side of the Fermi level E_{F} with respect to the energy potential of the first spacer layer 61 and the energy potential of the barrier layer 7.

This configuration makes it possible to easily construct a carrier trap region in the second spacer layer 62 before the carriers are trapped in each of the bulk trap region Tr1, the interface trap region Tr2, and the bulk trap region Tr3. Therefore, it is possible to effectively suppress or prevent the fluctuation in the threshold voltage of the HEMT 2, as described above.

Furthermore, as illustrated in FIGS. 1, 2, and 6, the channel layer 5 of the HEMT 2 is a nitride semiconductor. To give detailed description, the channel layer 5 is GaN.

Therefore, it is possible to construct the HEMT 2 having high voltage resistance, high heat resistance, high saturated electron velocity, and high channel electron concentration.

Further, as illustrated in FIGS. 1 to 3 and 6, the barrier layer 7 of the HEMT 2 is a nitride semiconductor having a band gap wider than the band gap of the channel layer 5. For example, the barrier layer 7 is Alₓ₃In_{[1-x3]}N (0<x3<1).

The first spacer layer 61 is a nitride semiconductor having a band gap wider than the band gap of the channel layer 5. For example, the first spacer layer 61 is Alₓ₁In_{y1}Ga_{[1-x1-y1]}N (0<x1<1, 0≤y1<1, and 0<x1+y1<1).

The second spacer layer 62 is a nitride semiconductor having a band gap narrower than the respective band gaps of the first spacer layer 61 and the barrier layer 7 and wider than the band gap of the channel layer 5. For example, the second spacer layer 62 is Alₓ₂In_{y2}Ga_{[1-x2-y2]}N (0<x2<1, 0<y2<1, and 0<x2+y2<1).

Furthermore, as illustrated in FIG. 2, the first spacer layer 61 has the Al composition profile having the maximal value in the thickness direction and the Ga composition profile having the minimal value in the thickness direction. Meanwhile, the second spacer layer 62 has an Al composition profile having a minimal value in the thickness direction and a Ga composition profile having a maximal value in the thickness direction.

To give detailed description, the Al composition ratio increases from the channel layer 5 to the first spacer layer 61, the Al composition ratio decreases from the first spacer layer 61 to the second spacer layer 62, and the Al composition ratio increases from the second spacer layer 62 to the barrier layer 7. Meanwhile, the Ga composition ratio decreases from the channel layer 5 to the first spacer layer 61, the Ga composition ratio increases from the first spacer layer 61 to the second spacer layer 62. and the Ga composition ratio decreases from the second spacer layer 62 to the barrier layer 7. An In composition ratio increases from the second spacer layer 62 to the barrier layer 7.

This makes it possible to generate concave energy potential for the second spacer layer 62, easily constructing the carrier trap region. Therefore, it is possible to effectively suppress or prevent the fluctuation in the threshold voltage of the HEMT 2, as described above.

Further, as illustrated in FIGS. 1 to 3, the thickness of the first spacer layer 61 is larger than the thickness of the second spacer layer 62 in the HEMT 2. For example, the thickness of the first spacer layer 61 is equal to or more than 0.5 nm.

Such a configuration makes it possible to secure a sufficient effect of the spacer layer 6, thereby effectively suppressing the alloy scattering. Therefore, the configuration makes it possible to achieve the high carrier mobility in the HEMT 2.

Furthermore, in the state where the positive bias is applied to the gate electrode 9. the conduction band E_{C} of the second spacer layer 62 is higher than the Fermi level E_{F} and the conduction band E_{C} of the channel layer 5 in the HEMT 2, as illustrated in FIG. 3.

Therefore, the carriers trapped in the energy potential region generated in the second spacer layer 62 flow between the pair of main electrodes 10 upon driving the HEMT 2, to be removed. That is, it is possible to effectively suppress or prevent the fluctuation in the threshold voltage of the HEMT 2.

Further, the HEMT 2 includes the insulating layer 8 between the barrier layer 7 and the gate electrode 9, as illustrated in FIG. 1. The insulating layer 8 is used as a gate insulating film to construct an MIS field-effect transistor.

Such a configuration makes it possible to effectively decrease a leakage current between the barrier layer 7 and the gate electrode 9 by the insulating layer 8 in the HEMT 2. In addition, this configuration makes it possible to apply a high gate voltage to the main electrodes 10 and the gate electrode 9 in the HEMT 2, thus achieving high voltage resistance.

Furthermore, the semiconductor device 1 according to the first embodiment includes the HEMT 2 described above. Because it is possible to effectively suppress or prevent the fluctuation in the threshold voltage of the HEMT 2 as described above, it is possible to achieve the semiconductor device 1 having stable characteristics.

### 2. Second Embodiment

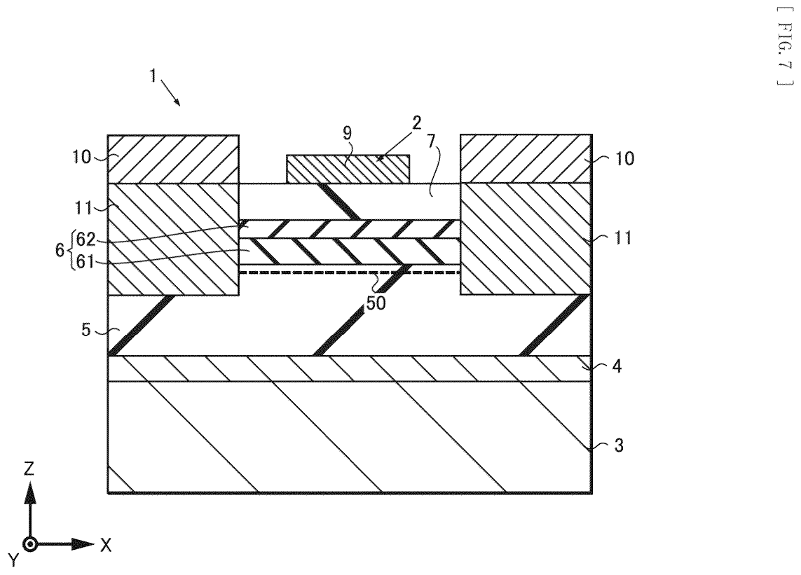

Description is given of the HEMT 2 according to the second embodiment of the present disclosure and the semiconductor device 1 including the HEMT 2 according to the second embodiment of the present disclosure with reference to FIG. 7.

It is to be noted that, in the second embodiment and embodiments described hereinafter, the same components or substantially the same components as the components of the first embodiment are denoted by the same reference numerals, and redundant description thereof is omitted.

### Configuration of HEMT 2 and Semiconductor Device 1

FIG. 7 illustrates an example of a vertical cross-sectional structure of a main part of the HEMT 2 and the semiconductor device 1 according to the second embodiment.

As illustrated in FIG. 7, the HEMT 2 according to the second embodiment includes a Schottky junction GaN HEMT (a Schottky junction field-effect transistor). That is, the gate electrode 9 is directly joined to the barrier layer 7 with no insulating layer 8 provided between the gate electrode 9 and the barrier layer 7. The gate electrode 9 includes a Schottky junction material.

Components other than the above are the same as the components of the HEMT 2 and the semiconductor device 1 according to the first embodiment.

### Workings and Effects

The HEMT 2 and the semiconductor device 1 according to the second embodiment make it possible to achieve workings and effects similar to the workings and effects achievable by the HEMT 2 and the semiconductor device 1 according to the first embodiment.

### 3. Third Embodiment

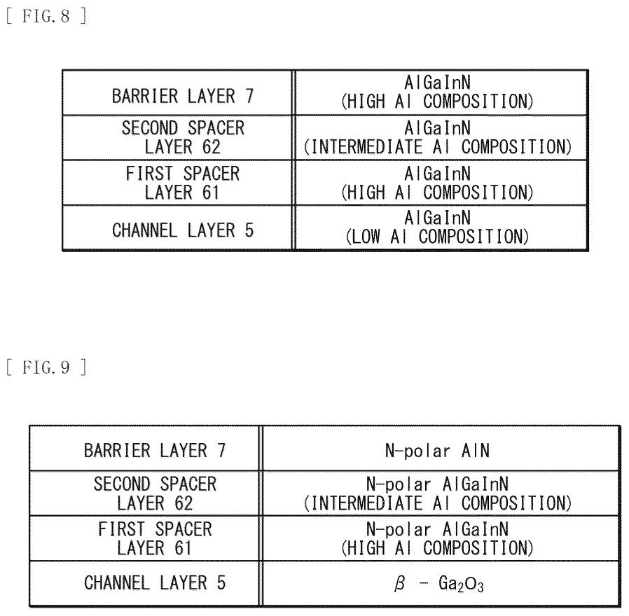

Description is given of the HEMT 2 according to the third embodiment of the present disclosure and the semiconductor device 1 including the HEMT 2 according to the third embodiment of the present disclosure with reference to FIG. 8.

### Configuration of HEMT 2 and Semiconductor Device 1

FIG. 8 illustrates an example of a configuration of a main part of the HEMT 2 and the semiconductor device 1 according to the third embodiment.

As illustrated in FIG. 8, the channel layer 5 of the HEMT 2 according to the third embodiment includes AlGaInN having low Al composition. The band gap of the channel layer 5 is, for example, 3.4 [eV] or more and 3.6 [eV] or less.

The first spacer layer 61 includes AlGaInN having high Al composition. The second spacer layer 62 includes AlGaInN having intermediate Al composition.

Further, the barrier layer 7 includes AlGaInN having high Al composition.

Components other than the above are the same as the components of the HEMT 2 and the semiconductor device 1 according to the first embodiment.

### Workings and Effects

The HEMT 2 and the semiconductor device 1 according to the third embodiment make it possible to achieve workings and effects similar to the workings and effects achievable by the HEMT 2 and the semiconductor device 1 according to the first embodiment.

Further, the channel layer 5, the first spacer layer 61, the second spacer layer 62, and the barrier layer 7 of the HEMT 2 each include similar AlGaInN with only the Al composition ratio being changed as appropriate. Such a configuration makes it possible to easily construct the HEMT 2 and the semiconductor device 1.

### 4. Fourth Embodiment

Description is given of the HEMT 2 according to the fourth embodiment of the present disclosure and the semiconductor device 1 including the HEMT 2 according to the fourth embodiment of the present disclosure with reference to FIG. 9.

### Configuration of HEMT 2 and Semiconductor Device 1

FIG. 9 illustrates an example of a configuration of a main part of the HEMT 2 and the semiconductor device 1 according to the fourth embodiment.

As illustrated in FIG. 9, the channel layer 5 of the HEMT 2 according to the fourth embodiment includes β-Ga₂O₃ as an oxide semiconductor material. The band gap of the channel layer 5 is, for example, 4.9 [eV].

The first spacer layer 61 includes N-polar AlGaInN. The AlGaInN of the spacer layer 6 has high Al composition. The second spacer layer 62 includes N-polar AlGaInN. The AlGaInN of the second spacer layer 62 has intermediate Al composition.

Further, the barrier layer 7 includes AlN.

Components other than the above are the same as the components of the HEMT 2 and the semiconductor device 1 according to the first embodiment.

### Workings and Effects

The HEMT 2 and the semiconductor device 1 according to the fourth embodiment make it possible to achieve workings and effects similar to the workings and effects achievable by the HEMT 2 and the semiconductor device 1 according to the first embodiment.

### 5. Fifth Embodiment

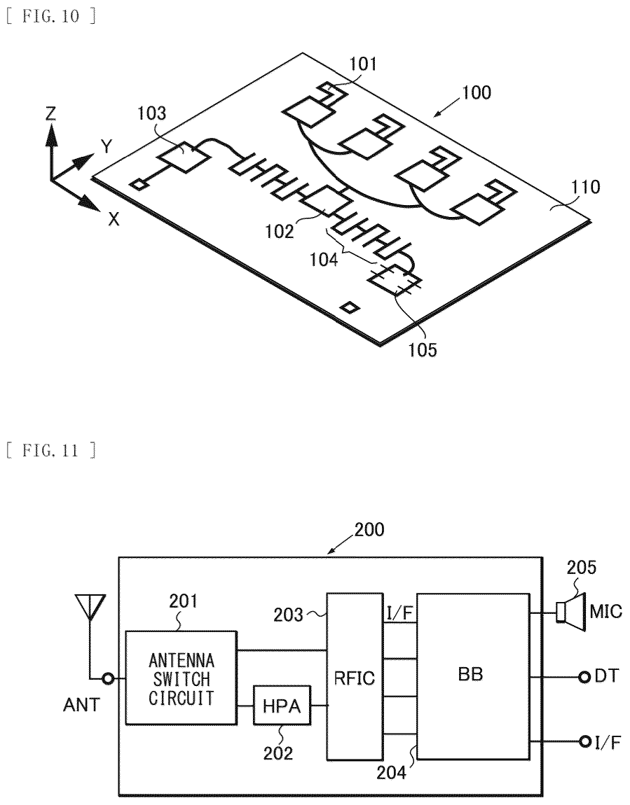

Description is given of a semiconductor module 100 according to the fifth embodiment of the present disclosure with reference to FIG. 10. The semiconductor module 100 constructs, for example, a wireless communication terminal.

### Configuration of Semiconductor Module 100

FIG. 10 illustrates an example of a schematic structure of the semiconductor module 100 according to the fifth embodiment.

The semiconductor module 100 according to the fifth embodiment is, for example, an antenna-integrated module including edge antennas 101 and front-end parts.

The edge antennas 101 disposed in an array and the front-end parts are mounted as one module on a substrate 110. The front-end parts include a switch 102, a low-noise amplifier 103, a bandpass filter 104, a power amplifier 105, and the like. The switch 102 is a high frequency switch circuit. The semiconductor module 100 is usable as, for example, a wireless communication terminal such as a communication transceiver.

The semiconductor module 100 includes, for example, the semiconductor device 1 mounted with the HEMT 2 according to any of the first embodiment to the fourth embodiment as a transistor configuring the switch 102, the low-noise amplifier 103, or the power amplifier 105.

### Workings and Effects

The semiconductor module 100 according to the fifth embodiment includes the semiconductor device 1 mounted with the HEMT 2, making it possible to achieve higher speed, higher efficiency, and lower power consumption of the wireless communication.

### 6. Sixth Embodiment

Description is given of a wireless communication terminal 200 as an electronic apparatus according to the sixth embodiment of the present disclosure with reference to FIG. 11.

### Configuration of Wireless Communication Terminal 200

FIG. 11 illustrates an example of a schematic block configuration of the wireless communication terminal 200 according to the sixth embodiment.

The wireless communication terminal 200 according to the sixth embodiment includes an antenna ANT, an antenna switch circuit 201, a high power amplifier (HPA) 202, a radio frequency integrated circuit (RFIC: radio frequency integrated circuit) 203, a baseband unit (BB) 204, an audio output unit (MIC) 205, a data output unit DT, and an interface unit I/F. The interface unit I/F includes, for example, a wireless LAN (W-LAN: wireless local area network), Bluetooth (registered trademark, Bluetooth (registered trademark)). The wireless communication terminal 200 is, for example, a mobile phone system having a plurality of functions such as voice and data communication or LAN connection.

The wireless communication terminal 200 includes the semiconductor device 1 mounted with the HEMT 2 according to any of the first embodiment to the fourth embodiment as a transistor configuring the antenna switch circuit 201, the high power amplifier 202, the radio frequency integrated circuit 203, or the baseband unit 204.

### Workings and Effects

The wireless communication terminal 200 according to the sixth embodiment includes the semiconductor device 1 mounted with the HEMT 2, making it possible to achieve higher speed, higher efficiency, and lower power consumption of the wireless communication. Therefore, in a case where the wireless communication terminal 200 is a portable communication terminal, it is possible for the wireless communication terminal 200 to further extend the uptime, thus further improving the portability.

### 7. Other Embodiments

The present technology is not limited to the above-described embodiments. and may be modified in various manners without departing from the gist thereof.

For example, it is possible to combine two or more of the HEMTs and the semiconductor devices according to the first to sixth embodiments described above.

A HEMT according to a first embodiment of the present disclosure includes a channel layer, a pair of main electrodes, a barrier layer, a gate electrode, and a first spacer layer.

Carriers flow through the carrier layer. The pair of respective main electrodes is coupled to one end and another end of the channel layer. The barrier layer is disposed at the channel layer and induces the carriers. The gate electrode is disposed at an intermediate part of the channel layer with the barrier layer interposed therebetween. The first spacer layer is disposed between the channel layer and the barrier layer and decreases alloy scattering.

Here, the HEMT further includes a second spacer layer. The second spacer layer is disposed between the first spacer layer and the barrier layer in a region overlapping the gate electrode and traps the carriers. The carriers are trapped in the second spacer layer before being trapped in the bulk trap region and the like present in the barrier layer. Such a configuration makes it possible to effectively suppress or prevent fluctuation in a threshold voltage of the HEMT.

Further, a semiconductor device according to a second embodiment of the present disclosure includes the HEMT according to the first embodiment.

Therefore, it is possible to achieve the semiconductor device including the HEMT that enables effective suppression or prevention of the fluctuation in the threshold voltage.

### Configuration of Present Technology

The present technology has the following configurations. According to the present technology of the following configurations, it is possible to effectively suppress or prevent fluctuation in a threshold voltage of a high electron mobility transistor (HEMT) in the high-electron mobility transistor, a semiconductor device, a high frequency switch circuit, a power amplifier, and a wireless communication terminal.

(1)

A high electron mobility transistor including:
a channel layer through which carriers are to flow;
a pair of respective main electrodes coupled to one end and another end of the channel layer:
a barrier layer that is disposed at the channel layer and induces the carriers;
a gate electrode disposed at an intermediate part of the channel layer with the barrier layer interposed therebetween;
a first spacer layer that is disposed between the channel layer and the barrier layer and decreases alloy scattering; and
a second spacer layer that is disposed between the first spacer layer and the barrier layer in a region overlapping the gate electrode and traps the carriers.
   (2)

The high electron mobility transistor according to (1), in which the second spacer layer has a band gap narrower than a band gap of the first spacer layer and a band gap of the barrier layer and wider than a band gap of the channel layer.

(3)

The high electron mobility transistor according to (2), in which the second spacer layer has concave energy potential formed to be curved toward a side of a Fermi level with respect to energy potential of the first spacer layer and energy potential of the barrier layer.

(4)

The high electron mobility transistor according to any one of (1) to (3), in which the channel layer is a nitride semiconductor.

(5)

The high electron mobility transistor according to any one of (1) to (4), in which the channel layer is GaN.

(6)

The high electron mobility transistor according to (5), in which the barrier layer is a nitride semiconductor having a band gap wider than a band gap of the channel layer.

(7)

The high electron mobility transistor according to (6), in which the barrier layer is Alₓ₃In_{[1-x3]}N, where 0<x3<1 is satisfied.

(8)

The high electron mobility transistor according to (7), in which the first spacer layer is a nitride semiconductor having a band gap wider than the band gap of the channel layer.

(9)

The high electron mobility transistor according to (8), in which the first spacer layer is Alₓ₁In_{y1}Ga_{[1-x1-y1]}N, where 0<x1<1, 0≤y1<1, and 0<x1+y1<1 are satisfied.

(10)

The high electron mobility transistor according to (9), in which the second spacer layer is a nitride semiconductor having a band gap narrower than a band gap of the first spacer layer and a band gap of the barrier layer and wider than the band gap of the channel layer.

(11)

The high electron mobility transistor according to (10), in which the second spacer layer is Alₓ₂In_{y2}Ga_{[1-x2-y2]}N, where 0<x2<1, 0<y2<1, and 0<x2+y2<1 are satisfied.

(12)

The high electron mobility transistor according to (11), in which the first spacer layer has an Al composition profile having a maximal value in a thickness direction and a Ga composition profile having a minimal value in the thickness direction.

(13)

The high electron mobility transistor according to (11) or (12), in which the second spacer layer has an Al composition profile having a minimal value in a thickness direction and a Ga composition profile having a maximal value in the thickness direction.

(14)

The high electron mobility transistor according to (13), in which
an Al composition ratio increases from the channel layer to the first spacer layer,
the Al composition ratio decreases from the first spacer layer to the second spacer layer, and
the Al composition ratio increases from the second spacer layer to the barrier layer.
   (15)

The high electron mobility transistor according to (14), in which
a Ga composition ratio decreases from the channel layer to the first spacer layer,
the Ga composition ratio increases from the first spacer layer to the second spacer layer, and
the Ga composition ratio decreases from the second spacer layer to the barrier layer.
   (16)

The high electron mobility transistor according to (15), in which an In composition ratio increases from the second spacer layer to the barrier layer.

(17)

The high electron mobility transistor according to any one of (1) to (16), in which the first spacer layer has a thickness larger than a thickness of the second spacer layer.

(18)

The high electron mobility transistor according to any one of (1) to (17), in which a thickness of the first spacer layer is equal to or more than 0.5 mm.

(19)

The high electron mobility transistor according to any one of (1) to (18), (22), and (23), in which, in a state where a positive bias is applied to the gate electrode, a conduction band of the second spacer layer is higher than a Fermi level and a conduction band of the channel layer.

(20)

A semiconductor device including a high electron mobility transistor, in which
the high electron mobility transistor includes
   a channel layer through which carriers are to flow,
   a pair of respective main electrodes coupled to one end and another end of the channel layer,
   a barrier layer that is disposed at the channel layer and induces the carriers,
   a gate electrode disposed at an intermediate part of the channel layer with the barrier layer interposed therebetween,
   a first spacer layer that is disposed between the channel layer and the barrier layer and decreases alloy scattering, and
   a second spacer layer that is disposed between the first spacer layer and the barrier layer in a region overlapping the gate electrode and traps the carriers.
      (21)

The high electron mobility transistor according to any one of (1) to (19), further including an insulating layer disposed between the barrier layer and the gate electrode, in which
the high electron mobility transistor includes an insulated gate field-effect transistor.
   (22)

The high electron mobility transistor according to any one of (1) to (19), in which
the gate electrode is coupled to the barrier layer through a Schottky junction, and
the high electron mobility transistor includes a Schottky junction field-effect transistor.
   (23)

A high frequency switch circuit including a high electron mobility transistor, in which
the high electron mobility transistor includes
   a channel layer through which carriers are to flow,
   a pair of respective main electrodes coupled to one end and another end of the channel layer,
   a barrier layer that is disposed at the channel layer and induces the carriers.
   a gate electrode disposed at an intermediate part of the channel layer with the barrier layer interposed therebetween,
   a first spacer layer that is disposed between the channel layer and the barrier layer and decreases alloy scattering, and
   a second spacer layer that is disposed between the first spacer layer and the barrier layer in a region overlapping the gate electrode and traps the carriers.
      (24)

A power amplifier including a high electron mobility transistor, in which
the high electron mobility transistor includes
   a channel layer through which carriers are to flow.
   a pair of respective main electrodes coupled to one end and another end of the channel layer,
   a barrier layer that is disposed at the channel layer and induces the carriers.
   a gate electrode disposed at an intermediate part of the channel layer with the barrier layer interposed therebetween,
   a first spacer layer that is disposed between the channel layer and the barrier layer and decreases alloy scattering, and
   a second spacer layer that is disposed between the first spacer layer and the barrier layer in a region overlapping the gate electrode and traps the carriers.
      (25) A wireless communication terminal including a high electron mobility transistor, in which
the high electron mobility transistor includes
   a channel layer through which carriers are to flow.
   a pair of respective main electrodes coupled to one end and another end of the channel layer,
   a barrier layer that is disposed at the channel layer and induces the carriers,
   a gate electrode disposed at an intermediate part of the channel layer with the barrier layer interposed therebetween,
   a first spacer layer that is disposed between the channel layer and the barrier layer and decreases alloy scattering, and
   a second spacer layer that is disposed between the first spacer layer and the barrier layer in a region overlapping the gate electrode and traps the carriers.

The present application claims the benefit of Japanese Priority Patent Application JP2022-084836 filed with the Japan Patent Office on May 24, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A high electron mobility transistor comprising:
a channel layer through which carriers are to flow:
a pair of respective main electrodes coupled to one end and another end of the channel layer;
a barrier layer that is disposed at the channel layer and induces the carriers;
a gate electrode disposed at an intermediate part of the channel layer with the barrier layer interposed therebetween;
a first spacer layer that is disposed between the channel layer and the barrier layer and decreases alloy scattering; and
a second spacer layer that is disposed between the first spacer layer and the barrier layer in a region overlapping the gate electrode and traps the carriers.

2. The high electron mobility transistor according to claim 1, wherein the second spacer layer has a band gap narrower than a band gap of the first spacer layer and a band gap of the barrier layer and wider than a band gap of the channel layer.

3. The high electron mobility transistor according to claim 2, wherein the second spacer layer bas concave energy potential formed to be curved toward a side of a Fermi level with respect to energy potential of the first spacer layer and energy potential of the barrier layer.

4. The high electron mobility transistor according to claim 1, wherein the channel layer is a nitride semiconductor.

5. The high electron mobility transistor according to claim 4, wherein the channel layer is GaN.

6. The high electron mobility transistor according to claim 5, wherein the barrier layer is a nitride semiconductor having a band gap wider than a band gap of the channel layer.

7. The high electron mobility transistor according to claim 6, wherein the barrier layer is Alₓ₃In_{[1-x3]}N, where 0<x3<1 is satisfied.

8. The high electron mobility transistor according to claim 7, wherein the first spacer layer is a nitride semiconductor having a band gap wider than the band gap of the channel layer.

9. The high electron mobility transistor according to claim 8, wherein the first spacer layer is Alₓ₁In_{y1}Ga_{[1-x1-y1]}N, where 0<x1<1, 0≤y1<1, and 0<x1+y1<1 are satisfied.

10. The high electron mobility transistor according to claim 9, wherein the second spacer layer is a nitride semiconductor having a band gap narrower than a band gap of the first spacer layer and a band gap of the barrier layer and wider than the band gap of the channel layer.

11. The high electron mobility transistor according to claim 10, wherein the second spacer layer is Alₓ₂In_{y2}Ga_{[1-x2-y2]}N, where 0<x2<1, 0<y2<1, and 0<x2+y2<1 are satisfied.

12. The high electron mobility transistor according to claim 11, wherein the first spacer layer has an Al composition profile having a maximal value in a thickness direction and a Ga composition profile having a minimal value in the thickness direction.

13. The high electron mobility transistor according to claim 12, wherein the second spacer layer has an Al composition profile having a minimal value in the thickness direction and a Ga composition profile having a maximal value in the thickness direction.

14. The high electron mobility transistor according to claim 13, wherein
an Al composition ratio increases from the channel layer to the first spacer layer,
the Al composition ratio decreases from the first spacer layer to the second spacer layer, and
the Al composition ratio increases from the second spacer layer to the barrier layer.

15. The high electron mobility transistor according to claim 14, wherein
a Ga composition ratio decreases from the channel layer to the first spacer layer,
the Ga composition ratio increases from the first spacer layer to the second spacer layer, and
the Ga composition ratio decreases from the second spacer layer to the barrier layer.

16. The high electron mobility transistor according to claim 15, wherein an In composition ratio increases from the second spacer layer to the barrier layer.

17. The high electron mobility transistor according to claim 1, wherein the first spacer layer has a thickness larger than a thickness of the second spacer layer.

18. The high electron mobility transistor according to claim 17, wherein the thickness of the first spacer layer is equal to or more than 0.5 nm.

19. The high electron mobility transistor according to claim 1, wherein, in a state where a positive bias is applied to the gate electrode, a conduction band of the second spacer layer is higher than a Fermi level and a conduction band of the channel layer.

20. A semiconductor device comprising a high electron mobility transistor, wherein
the high electron mobility transistor includes
a channel layer through which carriers are to flow,
a pair of respective main electrodes coupled to one end and another end of the channel layer,
a barrier layer that is disposed at the channel layer and induces the carriers,
a gate electrode disposed at an intermediate part of the channel layer with the barrier layer interposed therebetween,
a first spacer layer that is disposed between the channel layer and the barrier layer and decreases alloy scattering, and
a second spacer layer that is disposed between the first spacer layer and the barrier layer in a region overlapping the gate electrode and traps the carriers.
